(19) United States
(12) Patent Application Publication
(10) Pub. No.: US 2016/0223612 A1
(43) Pub. Date: Aug. 4, 2016

(54) IEEE 1149.1 STANDARD BASED TESTING METHODS USED IN PACKAGING

(71) Applicant: SINO IC TECHNOLOGY CO., LTD., Shanghai (CN)

(72) Inventors: Shouyin YE, Shanghai (CN); Jin WANG, Shanghai (CN); Jianhua QI, Shanghai (CN); Jianbo LING, Shanghai (CN); Hua WANG, Shanghai (CN); Dandan HAO, Shanghai (CN)

(21) Appl. No.: 14/744,790

(22) Filed: Jun. 19, 2015

(30) Foreign Application Priority Data
Jan. 31, 2015 (CN) 201510052286.2

(51) Int. Cl. G01R 31/3177

(52) U.S. Cl. CPC G01R 31/3177

(57) ABSTRACT

An IEEE 1149.1 standard based testing method used in packaging is disclosed. The method includes adding a TRD pin to each of n devices up to the IEEE 1149.1 standard. The TRD pins of the n devices are connected together to a common output terminal which is connected to a testing system. The first to m-th ones of the devices are tested by connecting the TDO and TRD pins of the m-th device and disconnecting the TDO and TRD pins of any one of the n devices other than the m-th, wherein m is a natural number that is smaller than or equal to n.

### CROSS-REFERENCES TO RELATED APPLICATIONS

This application claims the priority of Chinese patent application number 201510052286.2, filed on Jan. 31, 2015, the entire contents of which are incorporated herein by reference.

### TECHNICAL FIELD

The present invention relates to the field of integrated circuit (IC) testing and, in particular, to IEEE 1149.1 standard based testing methods used in packaging.

### BACKGROUND

IEEE 1149.1 standard is used for Boundary-Scan test of printed circuit boards (PCBs) and integrated circuits (ICs). The standard defines five standard pins: TDI, TDO, TCK, TMS and TRST pins. TDI is used for serial input of data (or a command), and TDO for serial output of data (or a command). TCK provides the clock to a design-for-testability logic, while TMS and TCK work together to provide the state of the logic. TRST is used to reset the design-for-testability logic. The testing will be started based on the obtainment of a test mode from a state machine and a command of the design-for-testability logic. During the testing of a PCB, as shown in FIG. 1, a number of devices (for example, four devices 101, 102, 103, 104) are assembled on the PCB, with their TCK, TMS and TRST pins respectively connected together, each upstream device having its TDO pin connected to the TDI pin of the adjacent downstream device, the TDI pin of the first device 101 serving as an input terminal of the whole set of the devices and connected to a testing system 105, and the TDO pin of the last device 104 serving as an output terminal of the set of the devices and also connected to the testing system 105. In this architecture, as each downstream device obtains a TDI signal from the TDO pin of the adjacent upstream device, failure or misassembly of any of the devices will disable the testing of all the devices. In addition, the connection between TDO and TDI pins of adjacent devices in the architecture is accomplished by physical means such as metal wires, which leads to inconvenience in separating the devices after the completion of the packaging. As a result, in this conventional solution, once the packaging is completed, even when one of the devices is found defective, it is impossible to locate it in this packaged form.

In the case of use in a 3D packaged system, the connection of the devices is similar to that established on the PCB, but differs in the devices being stacked in a three-dimensional configuration through the through-silicon via (TSV) process rather than being assembled on the same plane. This makes the separation of the devices after packaging more difficult and leads to malfunction of the whole assembly in case of failure of one of the devices. Any component that is newly stacked during packaging needs to be tested immediately in order to know whether it is problematic in a timely way. Additionally, if the component is found problematic, it will be replaced to avoid greater loss later. Therefore, testing during packaging is particularly important.

### SUMMARY OF THE INVENTION

The invention aims to solve the non-testability problem during packaging by providing IEEE 1149.1 standard based testing methods used in packaging.

To achieve this aim, according to a first aspect, an IEEE 1149.1 standard based testing method used in packaging is provided, including: providing n devices up to the IEEE 1149.1 standard and labeling the n devices with numbers 1 to n, wherein n is a natural number, each of the n devices includes a TCK pin, a TMS pin, a TRST pin, a TDI pin and a TDO pin, the TCK, TMS and TRST pins of the n devices are respectively connected together, the TDO pin of each upstream one of the n devices is connected to the TDI pin of an adjacent downstream one of the n devices, and the TCK, TMS, TRST and TDI pins of a first one of the n devices are connected to a testing system; adding a TRD pin to each of the n devices and connecting the TRD pins of the n devices together to a common output terminal, wherein the common output terminal is in connection with the testing system; and testing the first to m-th ones of the n devices by connecting the TDO and TRD pins of the m-th one of the n devices and disconnecting the TDO and TRD pins of any one of the n devices other than the m-th, wherein m is a natural number smaller than or equal to n.

Preferably, the TDO pin of each one of the n devices is connected to the TRD pin thereof via a switch, and the TDO and TRD pins of each of the n devices is connected or disconnected by executing a command to switch on or off the corresponding switch.

Preferably, the n devices are arranged and packaged in a plane.

Preferably, the n devices are arranged and packaged along a vertical direction.

Preferably, the TCK, TMS, TRST and TRD pins of the n devices are respectively connected together by a through-silicon via process.

Preferably, the TRD pin of each of the n devices and the common output terminal have a protection resistor connected in series therebetween.

To achieve the above aim, according to a second aspect, an IEEE 1149.1 standard based testing method used in packaging is provided, including:

a) providing n devices up to the IEEE 1149.1 standard and labeling the n devices with numbers 1 to n, wherein n is a natural number, each of the n devices includes a TCK pin, a TMS pin, a TRST pin, a TDI pin and a TDO pin, the TCK, TMS and TRST pins of the n devices are respectively connected together, the TDO pin of each upstream one of the n devices is connected to the TDI pin of an adjacent downstream one of the n devices, and the TCK, TMS, TRST and TDI pins of a first one of the n devices are connected to a testing system;

b) adding a TRD pin to each of the n devices and connecting the TRD pins of the n devices together to a common output terminal, wherein the common output terminal is in connection with the testing system; and

c) connecting the TDO and TRD pins of the n-th one of the n devices and disconnecting the TDO and TRD pins of any one of the n devices other than the n-th, testing the first to n-th ones of the n devices in accordance with the IEEE 1149.1 standard, determining whether the testing is successful, if the testing is successful, determining all the n devices as non-defective devices, and if the testing is not successful, carrying out the following steps:

d1) selecting a number m, wherein m is a natural number smaller than or equal to n;

d2) connecting the TDO and TRD pins of the m-th one of the n devices and disconnecting the TDO and TRD pins of any one of the n devices other than the m-th, testing the first to m-th ones of the n devices in accordance with the IEEE 1149.1 standard and recording a result of the testing; and

d3) if a defective one of the n devices is identifiable based on the result, then ending the testing; otherwise, returning to step d1.

Preferably, this method further includes testing a first one of the n devices to make sure the first one of the n devices is not defective prior to step c.

In the methods according to the present invention, each of the devices up to the IEEE 1149.1 standard is further provided with a TRD pin and a data return command for setting a state of connection between its TRD and TDO pins. The use of the TRD pins and the data return commands makes the TDO pin of each device possible to return data during packaging. This enables the assembly or stacking of IC components to be conducted in a manner in which each newly assembled or stacked component is tested in real time rather than being collectively tested after the whole assembly or stacking process, and also enables the location of any defective component during the assembly or stacking process, thereby improving the testing efficiency. The methods according to the present invention can be used to test various ICs with high versatility and consistency.

### BRIEF DESCRIPTION OF THE DRAWINGS

FIG. 1 is a diagram illustrating the principle of testing a PCB in accordance with the IEEE 1149.1 standard in the prior art.

FIG. 2 is a schematic illustration of a device in accordance with embodiments of the present invention.

FIG. 3 is a diagram illustrating the principle of testing devices during their stacking in accordance with Embodiment 1 of the present invention.

FIG. 4 is a diagram illustrating the principle of testing devices during their assembly in accordance with Embodiment 2 of the present invention.

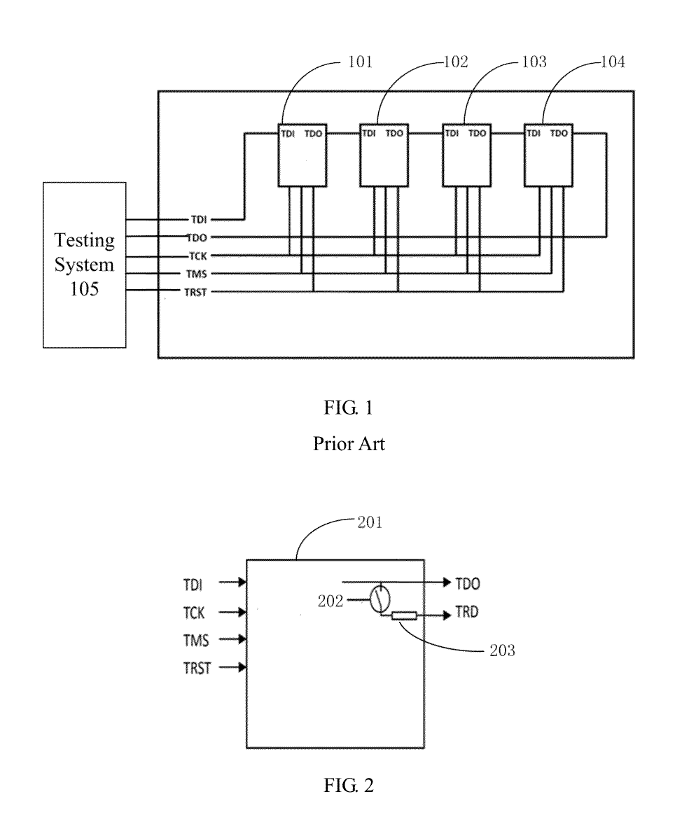

### DETAILED DESCRIPTION

Several specific embodiments of the present invention will be described in detail below by referencing the accompanying drawings. Advantages and features of the present invention will become better understood with reference to the following description and appended claims. Note that the accompanying drawings are provided in a very simplified form not necessarily presented to scale, with the only intention of facilitating convenience and clarity in explaining a few exemplary embodiments of the invention.

### Embodiment 1

FIG. 2 shows one of the devices 201 up to the IEEE 1149.1 standard during packaging. Each of the devices 201 includes a TCK pin, a TMS pin, a TRST pin, a TDI pin and a TDO pin, where the TCK pin is configured for test clock input, the TDI pin is configured for test data input, the TDO pin is configured for test data output, the TMS pin is configured for test mode selection and the TRST pin is configured for test reset input (effective at a low electrical level).

After the addition of a TRD pin, each of the devices 201 has the TCK, TMS, TRST, TDI, TDO and TRD pins. The devices 201 during packaging are three-dimensionally stacked by means of a through-silicon via (TSV) process. Specifically, the use of TSVs connects the TCK pins of the devices 201 together, the TMS pins of the devices 201 together, the TRST pins of the devices 201 together, and the TRD pins of the devices 201 together, respectively. The TDO pin of each upstream one of the devices 201 is connected to the TDI pin of the adjacent downstream one of the devices 201. The TDO pin of each device 201 is connected to its TRD pin via a switch 202, and the connection or disconnection of the TDO and TRD pins of each device 201 is accomplished by executing a command to switch on or off the corresponding switch 202.

Specifically, if the switch 202 corresponding to one of the devices 201 is turned on, the TRD and TDO pins of the device 201 are connected, and if the switch 202 is turned off, the TRD and TDO pins are disconnected from each other.

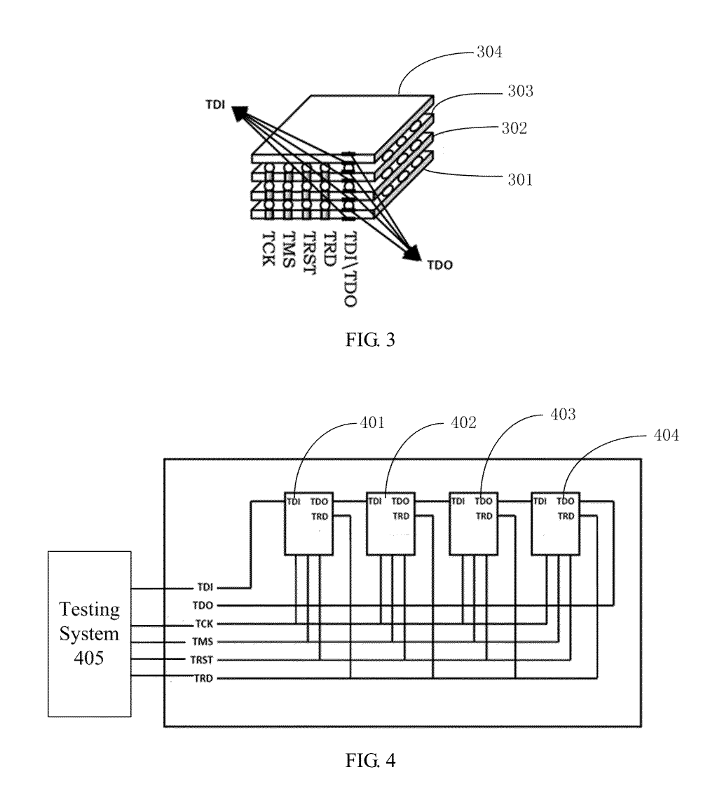

A process of testing devices during their stacking is described in detail with reference to FIG. 3.

The TCK, TMS, TRST, TDI and TRD pins of a first device 301 is first connected to a testing system. TDO and TRD pins of the first device 301 are then connected together based on a data return command for the first device 301. That is, the data return command for the first device 301 is configured such as to turn on the switch corresponding to the first device 301, thereby causing the TDO and TRD pins of the first device 301 to be interconnected and making it possible to test the first device 301 in accordance with the IEEE 1149.1 standard.

A second device 302 is then stacked. To this end, in the first place, the TDO pin of the first device 301 is connected to the TDI pin of the second device 302, and the TRD pin of the second device 302 is connected to the TRD pin of the first device 301. Next, the TDO pin of the first device 301 is disconnected from the TRD pin of the first device 301. This disconnection may be accomplished either by configuring the data return command for the first device 301 such as to turn off the switch corresponding to the first device 301, or by resetting the first device 301 through the TRST pin of the first device 301. Afterward, a data return command for the second device 302 is configured such as to turn on the switch corresponding to the second device 302, thereby causing the TDO and TRD pins of the second device 302 to be interconnected and making it possible to test the first device 301 and the second device 302 in accordance with the IEEE 1149.1 standard.

After that, a third device 303 is stacked on the second device 302. To do this, the data return command for the second device 302 is configured such as to turn off the switch corresponding to the second device 302. Alternatively, the second device 302 is reset through the TRST pin of the second device 302. As a result, the TDO pin of the second device 302 is disconnected from the TRD pin of the second device 302. Next, the TDO pin of the second device 302 is connected to the TDI pin of the third device 303, and TRD pin of the third device 303 is connected to both the TRD pin of the first device 301 and the TRD pin of the second device 302. Afterward, a data return command for the third device 303 is configured such as to turn on the switch corresponding to the third device 303, thereby causing the TDO and TRD pins of the third device 303 to be interconnected and making it possible to test the first device 301, the second device 302 and the third device 303 in accordance with the IEEE 1149.1 standard.

Thereafter, a fourth device 304 is further stacked in the same way as used to stack the second device 302 or the third device 303 such that the first device 301, the second device 302, the third device 303 and the fourth device 304 can be tested. With this done, the process of successive stacking and testing during the 3D packaging is completed.

While the present invention has been described above in conjunction with this embodiment in the context of usage in the 3D package of four devices, the invention is not limited in this regard, as in other embodiments the invention can also be used in the 3D packaging of any other number of devices depending on the practical needs. This will be well understood by those skilled in the art, and detailed description is thus omitted herein.

Further, during the process of stacking and testing, there is only one of the stacked devices is allowed to have its TRD pin connected to its TDO pin and all the device have their TRD pins connected together. In case of more than one stacked device with interconnected TRD and TDO pins, crosstalk will occur between signals at their TRD pins, which may cause damage to the devices. In order to prevent this, a protection resistor 203 (FIG. 2) may be further connected in series to the TRD pin of each of the devices to ensure their safety.

### Embodiment 2

The present invention can also be used in device testing during a PCB assembly process in a similar manner as the above-described testing method used in 3D packaging, detailed description of which is omitted herein.

In addition, the present invention can further be used to locate a defective device during the PCB assembly process. Although the testing of four devices to be arranged and packaged in a plane is described below with reference to FIG. 4 as a specific example, those skilled in the art will appreciate that the invention can also be used in the assembly of any other number of devices in other embodiments, of which, detailed description is omitted herein.

In the first place, the TCK, TMS, TRST, TDI and TRD pins of a first device 401 being assembled are connected to a testing system 405 and the TRD pins of all the four devices are connected together. In addition, the TDO pin of the first device 401 is connected to the TDI pin of a second device 402, the TDO pin of the second device 402 is connected to the TDI pin of a third device 403, the TDO pin of the third device 403 is connected to the TDI pin of a fourth device 404. Next, the TDO pin of the fourth device 404 is connected to the testing system 405 so as to test the first to fourth devices 401-404. In the event of failure or misassembly of any of the second device 402, the third device 403 and the fourth device 404 (in this embodiment, the first device 401 is assumed to be non-defective), there will be no signal communication between the connected TDI and TDO pins. To identify the location of the defective device, the TDO pin of the fourth device 404 is disconnected from the testing system 405 and data return commands are configured for the devices in a manner as described below, so that the location of the defective device can be easily identified and the TDO signal of the device immediately upstream to the defective device can be returned to the testing system 405 via its TRD pin. At the same time, all PCBs upstream to the defective device can still be tested.

Specifically, the data return command for the third device 403 is first configured such as to turn on the switch corresponding to the third device 403, thereby connecting the TDO and TRD pins of the third device 403. An attempt is then made to test the first device 401, the second device 402 and the third device 403. If the testing is successful, then the fourth device 404 is determined as a defective device. At the same time, the testing of the first device 401, the second device 402 and the third device 403 has been done. Otherwise, if the testing is not successful, it can be known that one of the second device 402 and the third device 403 is defective, and the data return command for the second device 402 is accordingly configured such as to cause the interconnection of its TDO and TRD pins. Another attempt is then made to test the first device 401 and the second device 402. If the testing is successful, then the third device 403 is determined as a defective device. At the same time, the testing of the first device 401 and the second device 402 has been done. If the testing is not successful, the second device 402 is determined as a defective device.

In summary, in the methods according to the present invention, each of the devices up to the IEEE 1149.1 standard is further provided with a TRD pin and a data return command for setting a state of connection between its TRD and TDO pins. The use of the TRD pins and the data return commands makes the TDO pin of each device possible to return data during packaging. This enables the assembly or stacking of IC components to be conducted in a manner in which each newly assembled or stacked component is tested in real time rather than being collectively tested after the whole assembly or stacking process, and also enables the location of any defective component during the assembly or stacking process, thereby improving the testing efficiency. The methods according to the present invention can be used to test various ICs with high versatility and consistency.

What are described above are merely preferred embodiments of the present invention which do not limit the scope of the invention in any way. Changes such as equivalent substitutions or modifications in any form made without departing from the inventive concept by any artisan skilled in the art to the features and details disclosed herein do not depart from the inventive concept and are within the scope of the invention.

What is claimed is:

1. An IEEE 1149.1 standard based testing method used in packaging, comprising:
providing n devices up to the IEEE 1149.1 standard and labeling the n devices with numbers 1 to n, wherein n is a natural number, each of the n devices includes a TCK pin, a TMS pin, a TRST pin, a TDI pin and a TDO pin, the TCK, TMS and TRST pins of the n devices are respectively connected together, the TDO pin of each upstream one of the n devices is connected to the TDI pin of an adjacent downstream one of the n devices, and the TCK, TMS, TRST and TDI pins of a first one of the n devices are connected to a testing system;
adding a TRD pin to each of the n devices and connecting the TRD pins of the n devices together to a common output terminal, wherein the common output terminal is in connection with the testing system; and
testing the first to m-th ones of the n devices by connecting the TDO and TRD pins of the m-th one of the n devices and disconnecting the TDO and TRD pins of any one of the n devices other than the m-th, wherein m is a natural number smaller than or equal to n.

2. The testing method according to claim 1, wherein the TDO pin of each one of the n devices is connected to the TRD pin thereof via a switch, and wherein the TDO and TRD pins of each of the n devices is connected or disconnected by executing a command to switch on or off the corresponding switch.

3. The testing method according to claim 1, wherein the n devices are arranged and packaged in a plane.

4. The testing method according to claim 1, wherein the n devices are arranged and packaged along a vertical direction.

5. The testing method according to claim 4, wherein the TCK, TMS, TRST and TRD pins of the n devices are respectively connected together by a through-silicon via process.

6. The testing method according to claim 1, wherein the TRD pin of each of the n devices and the common output terminal have a protection resistor connected in series therebetween.

7. An IEEE 1149.1 standard based testing method used in packaging, comprising:
a) providing n devices up to the IEEE 1149.1 standard and labeling the n devices with numbers 1 to n, wherein n is a natural number, each of the n devices includes a TCK pin, a TMS pin, a TRST pin, a TDI pin and a TDO pin, the TCK, TMS and TRST pins of the n devices are respectively connected together, the TDO pin of each upstream one of the n devices is connected to the TDI pin of an adjacent downstream one of the n devices, and the TCK, TMS, TRST and TDI pins of a first one of the n devices are connected to a testing system;
b) adding a TRD pin to each of the n devices and connecting the TRD pins of the n devices together to a common output terminal, wherein the common output terminal is in connection with the testing system; and
c) connecting the TDO and TRD pins of the n-th one of the n devices and disconnecting the TDO and TRD pins of any one of the n devices other than the n-th, testing the first to n-th ones of the n devices in accordance with the IEEE 1149.1 standard, determining whether the testing is successful, if the testing is successful, determining all the n devices as non-defective devices, and if the testing is not successful, carrying out the following steps:
d1) selecting a number m, wherein m is a natural number smaller than or equal to n;
d2) connecting the TDO and TRD pins of the m-th one of the n devices and disconnecting the TDO and TRD pins of any one of the n devices other than the m-th, testing the first to m-th ones of the n devices in accordance with the IEEE 1149.1 standard and recording a result of the testing; and
d3) if a defective one of the n devices is identifiable based on the result, then ending the testing; otherwise, returning to step d1.

8. The testing method according to claim 7, further comprising testing a first one of the n devices to make sure the first one of the n devices is not defective prior to step c.

9. The testing method according to claim 7, wherein the TDO pin of each one of the n devices is connected to the TRD pin thereof via a switch, and wherein the TDO and TRD pins of each of the n devices is connected or disconnected by executing a command to switch on or off the corresponding switch.

10. The testing method according to claim 7, wherein the n devices are arranged and packaged in a plane.

11. The testing method according to claim 7, wherein the n devices are arranged and packaged along a vertical direction.

12. The testing method according to claim 11, wherein the TCK, TMS, TRST and TRD pins of the n devices are respectively connected together by a through-silicon via process.

13. The testing method according to claim 7, wherein the TRD pin of each of the n devices and the common output terminal have a protection resistor connected in series therebetween.
